(19) United States
(12) Patent Application Publication
(10) Pub. No.: US 2005/0232056 A1
(43) Pub. Date: Oct. 20, 2005

(54) Electronic device with data storage device

(75) Inventor: Katarzyna Leijten-Nowak, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., Eindhoven (NL)

(21) Appl. No.: 10/525,811

(22) PCT Filed: Jul. 31, 2003
(86) PCT No.: PCT/IB03/03720

§ 371 Date: Feb. 25, 2005

(30) Foreign Application Priority Data
Aug. 29, 2002 (EP) 02078548.1

(51) Int. Cl. G11C 8/00

(52) U.S. Cl. 365/230.01

(57) ABSTRACT

An electronic device (100) has a data storage device (120) for storing N data elements, the data storage device (120) comprising a first collection (122) of data storage elements (130). The first collection (122) of data storage elements (130) is accessible through an address decoder (140). In a shift register mode of the data storage device (120), the address decoder (140) is responsive to an address generator (160) comprising a modulo-N counter. Rather than having to shift data elements from one data storage element (130) to another, the address generator (160) generates a pointer to the data storage element (130) that contains the data element that is to be shifted out of the shift register. This has the advantage that the output of a predecessor data storage element (130) in a shift register need not be interconnected to the input of its successor. In addition, the amount of data traffic required during a shift is drastically reduced. The invention is particularly relevant to reconfigurable logic devices that use look-up tables for implementing shift registers.

The present invention relates to an electronic device comprising a data storage device for storing N data elements, N being an integer with a value of at least two, the data storage device comprising a first collection of data storage elements, and an address decoder having an output coupled to the first collection of data storage elements for accessing a data storage element from the first collection of data storage elements on the basis of a bit pattern.

Nowadays, virtually all electronic devices, e.g., integrated circuits (ICs), systems-on-chip (SoCs) and so on, include a data storage device coupled to an address decoder for storing and retrieving data from a particular data storage element of the data storage device based on a bit pattern, i.e., an address. Such a data storage device may be a dedicated storage device, e.g., a volatile or non-volatile memory, or a reconfigurable logic device (RLD), e.g. an field-programmable gate array (FPGA), which can be configured to operate as data storage device in a data storage mode of the RLD. An application of such a data storage device may be a shift register implementation, which implies that the data stored in the data storage device is retrieved from the data storage device a fixed number of clock cycles later.

RLDs from the Virtex-II family by Xilinx, as described in the Virtex-II Platform FPGA handbook, Xilinx, 2000, includes a look-up table (LUT) that is operable as a shift register. To this end, the data storage elements of the LUT are implemented by means of interconnected latches, which are arranged to ripple data from latch to latch under control of a control signal. This way, the LUT operates in a pipeline-like fashion with the data element being shifted into the first data storage element and being retrieved from the last data storage element in the pipeline after it has been shifted through the complete pipeline.

It is a disadvantage that for shift register implementations of data storage devices like the LUT in the RLD from Xilinx the data storage elements have to be interconnected to implement the shift register behavior of the device because this interconnection introduces additional wiring, i.e., interconnects, between the various data storage elements of the first collection of data storage elements, as well as additional transistors for disconnecting the interconnections if the electronic device is operated in a non-shift register configuration.

Amongst others, it is an object of the invention to provide an electronic device of the opening paragraph that allows for a more efficient implementation of the first collection of data storage elements for shift-register implementations.

Now, the object of the invention is realized by an input of the address decoder being coupled to an address generator comprising a modulo-N counter for generating the bit pattern. This has the advantage that it is no longer necessary to physically shift data from a data storage element to the next data storage element in the data storage device. Therefore, the interconnections between the various data storage elements that enable this shifting of data can be omitted. Instead, the address generator generates addresses from an address space that represents the temporal behavior of a shift register. In other words, rather than physically moving data elements from one data storage element to another, a reference, e.g., an address, of the data element that has to be retrieved from the data storage device is generated on the fly. This has the additional advantage that only a single data storage element has to be overwritten, i.e., the data storage element from which the data element is retrieved, rather than having to overwrite all N data storage elements in the known implementations of shift registers.

Advantageously, the electronic device comprises a look-up table being operable as the first collection of data storage elements in a data storage configuration of the electronic device.

The present invention is especially useful for application in RLDs based on LUTs, because in such devices both the amount of hardware required and the performance of the device are bottlenecks in the design and use of the devices. Thus, the reduced amount of required interconnect and the reduced amount of data communication of shift register implementations of the present invention contribute to an increase in performance and a reduction in design effort for such RLDs. More importantly, the area overhead of the RLD is reduced, because no additional switches, e.g., transistors, are needed to disconnect the data paths between the data storage elements if the RLD is operated in a non-shift register configuration.

It is an advantage if the electronic device is arranged to perform a read operation on the data storage element in a first part of a clock cycle; and to perform a write operation on the data storage element in a second part of the clock cycle.

This functionality, which may be implemented as a Random Access Memory (RAM) type architecture of the data storage device, prevents read/write conflicts during a single clock cycle, which implies that a single address decoder can be used for both reading and writing from and to a data storage element, which is a substantial advantage in terms of area, especially in the field of RLDs, where usually separate decoders are being used for writing and reading. The functionality may be implemented by a configurable switch that couples the data input of the data storage device to a memory element of the data storage element; the configurable switch being conductive during at least a part of the second part of the clock cycle. Only if this switch is conductive, i.e. during the write cycle, can data be stored in the data storage element.

It is a further advantage if the data storage device further comprising a second collection of data storage elements at least during a data storage mode of the electronic device; the electronic device further comprising control circuitry coupled between the control signal and the data storage device for selecting one of the first and second collections of data storage elements responsive to a selection signal.

Such an arrangement allows for shift register implementations that have a larger size than the size of a single collection of data storage elements, e.g., a LUT, with the control circuitry controlling the selection of the appropriate collection of data elements. The second collection of data storage elements may be responsive to a different address decoder or to the address decoder of the first collection of data storage elements, e.g., as is the case for multiple-output LUTs. The collections of data storage elements need not be permanently integrated in the data storage device; for instance, if the electronic device is a reconfigurable device, the second collection of data storage elements may be added to the data storage device in a data storage configuration, e.g., a memory configuration or a shift register configuration, of the electronic device

It is yet a further advantage if the data storage device comprises a third collection of data storage elements and a fourth collection of data storage elements being at least in the data storage configuration of the electronic device, the third collection and the fourth collection of data storage elements being responsive to a further address decoder; the control circuitry further being arranged to select one of the first, second, third and fourth second data storage elements responsive to the selection signal and a further selection signal. The inclusion of a larger number of collections of data storage elements, e.g., LUTs, under control of the control circuitry allows for the construction of a large size shift registers, which can be particularly useful for applications that require large shift registers for the buffering or delaying of data, e.g., digital signals processors (DSPs). Such an architecture may be configured by the most significant bits from the bit pattern.

It is a further advantage if the control circuitry further comprises a configuration network for configuring a size of the data storage device. The inclusion of such a network enables the dynamic selection of the number of the collections of data storage elements that are temporarily included in the data storage device, for instance during its implementation as a shift register.

The electronic device and parts thereof according to the invention are described in more detail and by way of non-limiting examples with reference to the accompanying drawings, wherein:

FIG. 1 depicts an embodiment of an electronic device of the present invention;

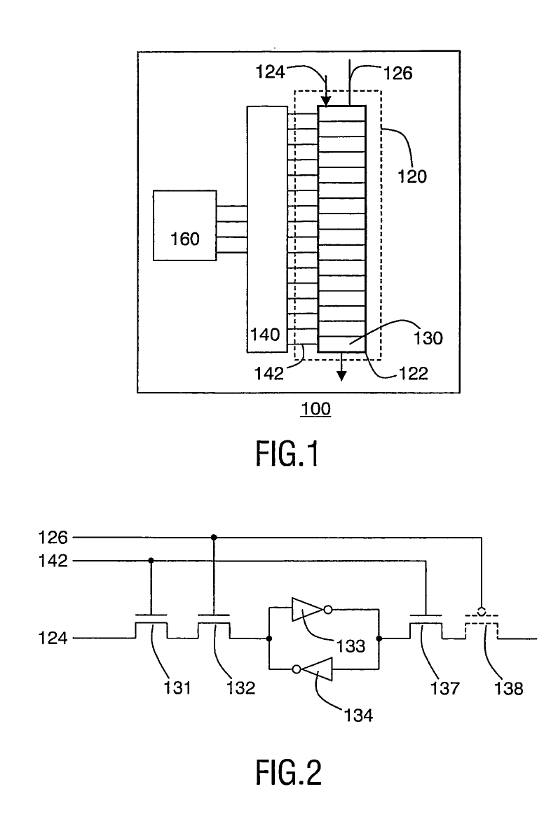

FIG. 2 depicts an exemplary data storage element;

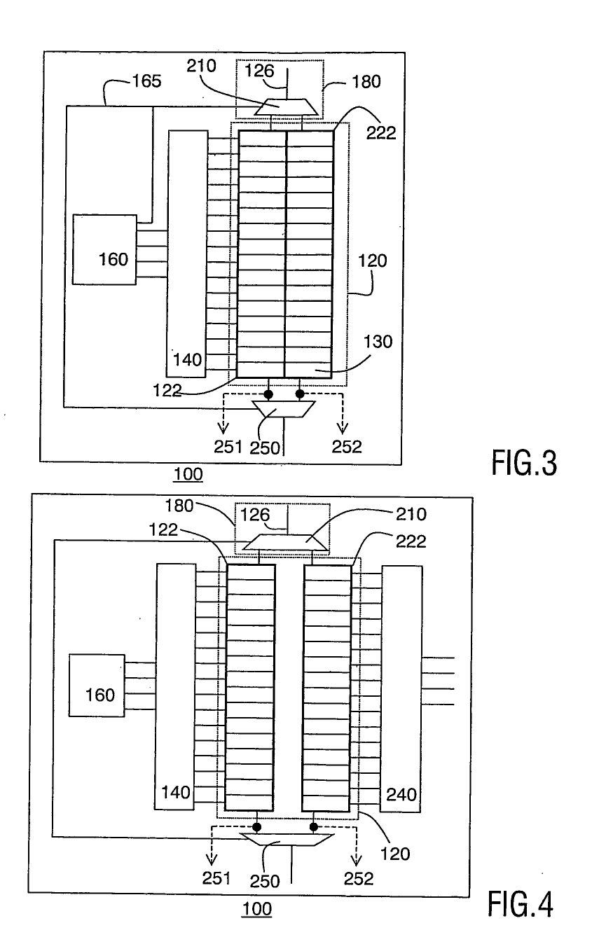

FIG. 3 depicts another embodiment of an electronic device of the present invention;

FIG. 4 depicts yet another embodiment of an electronic device of the present invention;

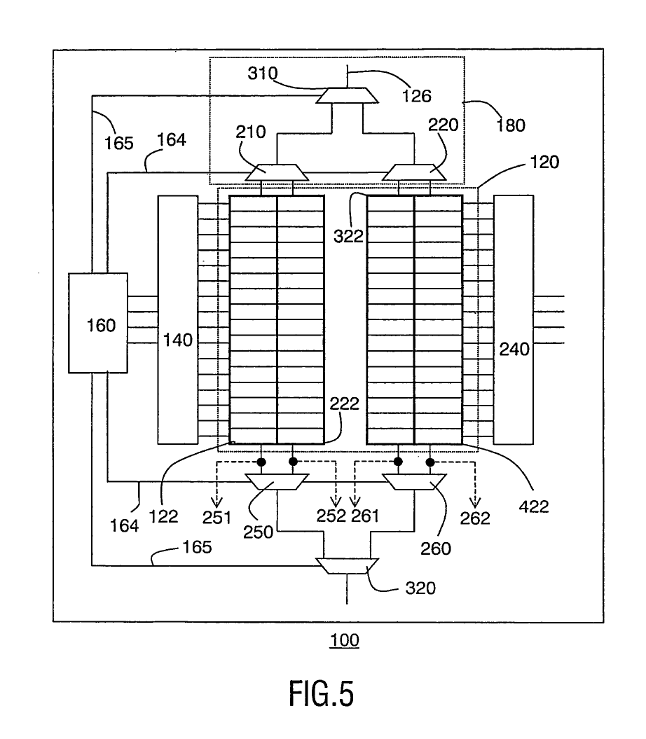

FIG. 5 depicts a further embodiment of an electronic device of the present invention;

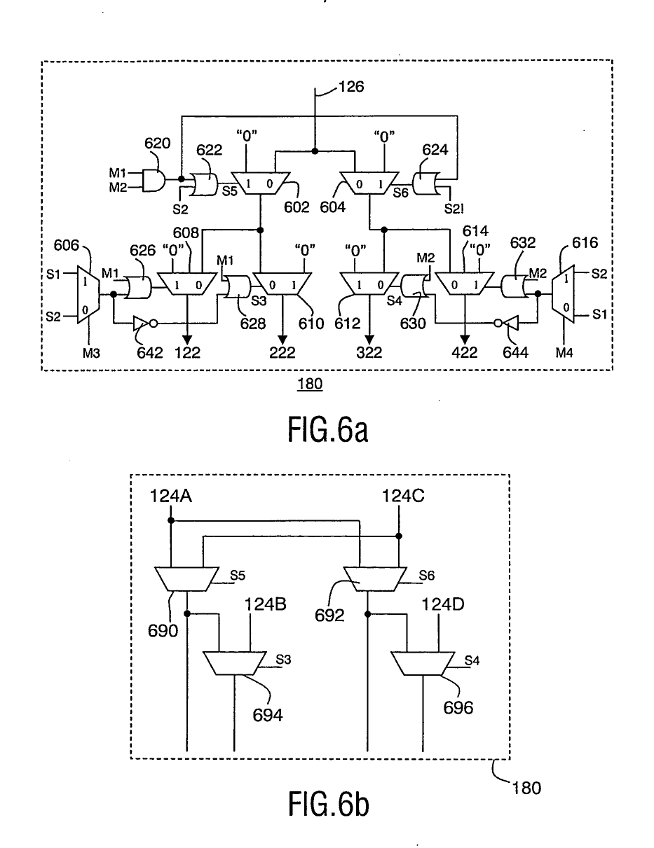

FIG. 6a depicts an embodiment of a control circuit of the present invention; and

FIG. 6b depicts an embodiment of a data routing network of the present invention.

In FIG. 1, electronic device 100 includes a data storage device 120 for storing N data elements 130, N being an integer with a value of at least two; in FIG. 1, N is sixteen, this particular number being chosen for reasons of mere example only. The data storage device 120 has a first collection 122 of data storage elements 130. The first collection 122 of data storage elements 130 is coupled to a control input 126 and a data input 124. The first collection 122 of data storage elements 130 may be a dedicated data storage device, e.g. a volatile or non-volatile memory, or a look-up table (LUT), in which case the electronic device 100 may be a RLD. In FIG. 1, the first collection 122 of data storage elements 130 combined with address decoder 140 would form a 4-input LUT.

The electronic device 100 also includes an address decoder 140 having an output 142 coupled to the first collection 122 of data storage elements 130 for accessing a data storage element 130 from the first collection 122 of data storage elements 130 on the basis of a bit pattern, e.g., an address of the data storage element 130 provided through a plurality of outputs 142. Each data storage element 130 is coupled to an output 142, which serves as a select line for the data storage element 130. An input of the address decoder 140 is coupled to an address generator 160 comprising a modulo N counter for generating the bit pattern responsive to control signal 126 or another control signal being synchronized with control signal 126. Control signal 126 may be a clock signal, with the address generator 160 being responsive to one of the edges of the clock signal. The modulo N counter may be implemented in a separate data storage device, e.g. a separate LUT.

This arrangement is particularly suitable for implementing shift register functionality in the data storage device 120. The modulo N counter of address generator 160 ensures that at each occurrence of a control signal, i.e., control signal 126 or its synchronized counterpart, a next data storage element 130 is selected in data storage device 120. This way, all N data storage elements 130 are selected once during N control cycles, preferably in a cyclic way. Basically, the address generator 160 generates a pointer to a data storage element 130, that pointer being pointed once to each of the N data storage elements 130, thereby implementing an N-stage shift register without having to actually shift data elements from one data storage element 130 to another. Therefore, the data storage elements 130 no longer need an interconnected data path, i.e., a data output from the predecessor data storage element 130 being connected to a data input of its successor in the shift register, because the data is no longer physically rippled through the shift register. This has the additional advantage of reduced data communication and increased data integrity, because the physical rippling of data through a shift register means that for each data storage element 130 care has to be taken that a read action takes place before a write action. The implementation of the present invention reduces this problem to a single data storage element 130, i.e., the element being selected by address generator 160.

In addition, it is emphasized that the modulo N counter may be programmable, i.e., that N may be dynamically defined. This allows for implementations where the actual size of the shift register is smaller than the total capacity of a data storage device 120.

In case of a multi-functional implementation of the first collection 122 of data storage elements 130, e.g., a LUT implementation within a RLD, the coupling between the address decoder 140 and the address generator 160 may be configurable, in order to disconnect or bypass the address generator 160 in order to access the inputs of address decoder 140, for instance during a memory mode or a combinatorial mode of the first collection 122 of data storage elements 130. Alternatively, the address generator 160 may become transparent in the absence of a control signal 126 or its synchronized counterpart.

Now, the remaining FIGS. will be described in backreference to FIG. 1. Corresponding reference numerals will have similar meanings unless explicitly stated otherwise. In FIG. 2, an example implementation of a data storage element 130 is shown. Data storage element 130 has a memory element formed by interconnected inverters 133 and 134. The input of the memory element is interconnected to a portion of the data input 124 of the first collection 122 of data storage elements 130. This portion includes a first enable switch 131 and a second enable switch 132. First enable switch 131 is controlled by a select signal via output 142 from the address decoder 140. Second enable switch 132 is controlled by control signal 126, which may be a clock signal, an inverted clock signal or another multi-phase signal. The memory element has an output including third enable switch 137 being controlled by the select signal from output 142. All switches are preferably implemented as transistors, as shown in FIG. 2, although other implementations are feasible.

During a first phase of the control signal 126, second enable switch 132 is disabled and updating of the memory element formed by inverters 133 and 134 is prohibited, even if the data storage element 130 is selected by address decoder 140, i.e., first and third enable switches 131 and 137 are enabled via output 142. This mechanism ensures that during a first phase of the control signal 126 data stored in the memory element cannot be overwritten. Hence, the first phase of the control signal 126 is used to read out data element from data storage element 130. In the second phase of control signal 126, second enable switch 132 is enabled and the memory element can be updated.

It is emphasized that the implementation of data storage element 130 shown in FIG. 2 is shown by way of a non-limiting example only. Other equivalent implementations of the data storage element 130 are equally feasible without departing from the scope of the present invention.

The present invention may also be applied to data storage devices that are capable of storing N data elements in K collections of data storage elements, each collection having a capacity of M data storage elements; i.e., N=K*M, with K and M both being integers with a value of at least two. This way, larger shift registers comprising several collections of data storage elements may be built. FIG. 3 shows an implementation of an electronic device 100 that is capable of implementing a shift register in such a way.

The data storage device 120 of electronic device 100 has a first collection 122 and a second collection 222 of data storage elements 130, both collections 122 and 222 being accessible by address decoder 140. Data storage device 120 may be a dedicated multi-column memory device or a multi-column, multi-purpose device, e.g. a multiple-output LUT. The selection of the appropriate data storage element 130 from the appropriate collection, i.e., first collection 122 or second collection 222, is controlled by control circuitry 180 implementing demultiplexer functionality, which is symbolically depicted by demultiplexer 210, which has an input coupled to control signal 126 and outputs coupled to the first collection 122 and the second collection 222 of data storage elements 130. The demultiplexer 210, or the equivalent control circuitry, is responsive to a selection signal 165, e.g., the most significant bit from the outputs of the address generator 160. It will be obvious that a similar control architecture may be used to demultiplex a global data input 124 not shown to the first collection 122 and second collection 222. Alternatively, if each of the first collection 122 or second collection 222 of data storage elements 130 has a separate data input, a collection of multiplexers may be used to route the input to the appropriate collection of data storage elements, in analogy with the teachings of FIG. 6a and FIG. 6b. It may be advantageous to add a multiplexer 250 to the data outputs of the first collection 122 and second collection 222 of data storage elements 130, in order to convert a multiple-output data storage device into a single output data storage device during the implementation of the shift register functionality. Multiplexer 250 may be controlled by selection signal 165, e.g., the most significant bit. The first collection 122 of data storage elements 130 may have a bypass path 251 around multiplexer 250 and the second collection 222 of data storage elements 130 may have a bypass path 252 around multiplexer 250 for operating the data storage device 120 in a multiple-output mode when another functionality, e.g., implementation of a logic function in a combinatorial mode of a LUT, than the shift register implementation is required. Obviously, one of the bypass paths may be omitted if the multiplexer 250 can be tied to a fixed selection signal in this mode.

FIG. 4 is described in backreference to FIG. 3. Corresponding reference numerals will have similar meanings unless explicitly stated otherwise. FIG. 4 shows an alternative implementation of the data storage device 120 shown in FIG. 3. The first collection 122 of data storage elements 130 is still accessible by address decoder around multiplexer 250. The second collection 222 of data storage elements 130 is accessible by a further address decoder 240. In the shift register implementation mode of data storage device 120, further address decoder 240 is coupled to the address generator 160, or to another address generator that operates in a lock-step mode, i.e., synchronized, with the address generator 160. Basically, the electronic device 100 in FIG. 4 joins independent collections of data storage elements; e.g., independent LUTs from separate FPGA cells, into a single data storage device 120 for implementing a shift register.

FIG. 5 is described in backreference to FIG. 4. Corresponding reference numerals will have similar meanings unless explicitly stated otherwise. In FIG. 5, the concepts shown in FIG. 3 and FIG. 4 have been combined. Electronic device 100 includes a data storage device 120 that has a first collection 122, a second collection 222, a third collection 322 and a fourth collection 422 of data storage elements 130. The first collection 122 and the second collection 222 of data storage elements 130 are accessible by address decoder 140, whereas the third collection 322 and the fourth collection 422 of data storage elements 130 are accessible by a further address decoder 240. Both address decoders 140 and 240 are coupled to address generator 160, or a combination of synchronized address generators, in a shift register implementation mode of the data storage device 120. It is emphasized that data storage device 120 may comprise a first collection 122, a second collection 222, a third collection 322 and a fourth collection 422 of data storage elements 130 only during the shift register implementation mode, as a result of the appropriate configuration of the control circuitry. This will be explained in more detail later.

The control circuitry 180 now typically implements a single input/four output demultiplexer functionality, which has been symbolically depicted by demultiplexers 210, 220 and 310. The demultiplexers may be controlled by a selection signal 165 and a further selection signal 164, e.g., the two most significant bits that are generated by the address generator 160. Although shown for control signal 126, it will be appreciated that similar control circuitry may be implemented for the various data signals 124. On the output side of data storage device 120, additional control circuitry implementing the multiplexer functionally that is symbolically depicted by multiplexers 250, 260 and 320 may be used to configure the data storage device 120 into a single output mode during its shift register implementation or another data storage mode of electronic device 100. Bypass paths 251, 252, 261 and 262 may be present to allow a multiple output configuration of the first collection 122, a second collection 222, a third collection 322 and a fourth collection 422 of data storage elements 130.

FIG. 5 shows a combination of two two-output data storage devices, e.g. two two-output LUTs, into a single data storage device 120 for implementing a shift register. It will be obvious to a person skilled in the art that other combinations, e.g., several single-output data storage devices, several multiple-output devices or a combination of the two, can be made without departing from the scope of the present invention.

FIG. 6a shows an exemplary embodiment of a first part of control circuitry 180. In this particular example, a configuration network for the data storage device 120 shown in FIG. 5 is given. The control circuitry 180 is responsive to configuration signals M1-M4, as well as to external selection signals S1 and S2 and internal selection signals S3-S6. The selection signals S1 and S2 correspond with the selection signals 164 and 165 shown in FIG. 5. In this embodiment, control circuitry 180 has a twofold purpose; firstly, control circuitry 180 is arranged to configure an operational mode of the data storage device 120 in response to configuration signals M1-M4, and secondly, control circuitry 180 is arranged to select the appropriate collection of data storage elements 130, i.e., one of the first collection 122, a second collection 222, a third collection 322 and a fourth collection 422 of data storage elements 130, in response to selection signals S1-S6.

Multiplexers 602, 604, 608, 610, 612 and 614 are arranged to propagate the control signal 126 to the appropriate collection of data storage elements in a memory mode, e.g., a shift register implementation, of the data storage device 120. To this end, they have their input terminal 0, i.e., the input terminals that are selected when a logic ‘0’ is driven to the control terminal of the multiplexers, coupled to a signal path of this control signal. The input terminals 1, i.e., the input terminals that are selected when a logic ‘1’ is driven to the control terminals of the multiplexer, are coupled to a fixed logic value source providing a logic ‘0’, e.g., a pull-down transistor. The latter signal may be selected when the collections 122, 222, 322, 422 of data storage elements 130 are to be operated in a read-only mode, e.g., an implementation of a logic function in a combinatorial mode of a LUT.

Configuration bits M1 and M2, which configure the subdevices, e.g., the two-output LUTs, formed by the first collection 122 and second collection 222 of data storage elements 130, and by the third collection 322 and fourth collection 422 of data storage elements 130 respectively, define whether or not these subdevices are to be operated in a synchronous mode, i.e., in a mode responsive to control signal 126. In this exemplary implementation, a value ‘1’ for M1 or M2 means that the corresponding subdevice should be configured in a read-only mode. If one of these configuration bits has a value ‘0’, the corresponding subdevice is to be operated in a memory mode, and the data storage device 120 then includes one of the subdevices. If both configuration bits M1 and M2 have value ‘0’, both are configured to be operated in a memory mode, and data storage device 120 includes both subdevices 122/222 and 322/422. Selection bits S1 and S2 select the appropriate collection of data storage elements 130. If both subdevices are included in data storage device 120, S1 and S2 represent the two most significant bits that are generated by the address generator 160. If only one of the subdevices is included in data storage device 120, S1 is set equal to S2. Alternatively, S2 can be tied to a fixed value, which may be programmable.

AND gate 620 has inputs coupled to M1 and M2. Its output is coupled to an input of OR gates 622 and 624, which have their other input connected to S2 and the inverse, i.e., negation of S2 respectively. The latter has been labeled S2!. The outputs of OR gates 622 and 624 are arranged to provide selection signals S5 and S6 to the control terminals of multiplexers 602 and 604, respectively. This arrangement ensures that, if M1 and M2 are both a logic ‘1’ that both multiplexers 602 and 604 will output the fixed logic ‘0’. In addition, it ensures that when at least one of M1 and M2 is a logic ‘0’, only the subdevice that corresponds with the appropriate value of S2 is capable of receiving the control signal 126. For instance, if M1=0, M2=0 and S2=1, selection signal S5 will be ‘1’ and selection signal S6 will be ‘0’.

Multiplexers 606 and 616 have their inputs connected to S1 and S2 under control of configuration bits M3 and M4. These multiplexer can be used to configure whether the subdevices are to operate as a single entity or as independent devices. In the former case, both multiplexers are connected to S1, whereas in the latter case multiplexer 606 is connected to S1 and multiplexer 616 is connected to S2 or vice versa. In the latter case, it may be advantageous for the independent devices to be responsive to independent control signals. The output signal and the negation of the output signal of multiplexer 606 are provided to OR gates 626 and 628 respectively. The negation of the output signal is implemented by inverter 642. OR gates 626 and 628 have their other input connected to M1. OR gate 626 provides selection signal S3 to the control terminal of multiplexer 608, whereas OR gate 628 provides its output signal to the control terminal of multiplexer 610. Thus, if M1 has value ‘1’, both collections 122, 222 of data storage elements 130 will be in a read-only mode, and if M1 has value ‘0’, the value of S1 or S2 will decide which collection of data storage elements 130 is switched to a memory mode. It will be understood that OR gate 630, which generates selection signal S4, and OR gate 632 implement an analogous control mechanism for collections 322, 422 of data storage elements 130 via multiplexers 612, 614 under the influence of inputs M2 and S1 or S2 and their negation implemented by inverter 644.

It will be obvious to those skilled in the art that many variations can be made to the control circuitry shown in FIG. 6a, which has been shown as a mere example only. Alternative implementations using different combinations of logic gates are equally acceptable. Less complex control circuitry may be used if the electronic device 100 does not require the level of flexibility provided by control circuitry 180. Alternatively, more complex control circuitry may be used if the electronic device 100 requires more flexibility than the level of flexibility provided by control circuitry 180. Also, it will be obvious to those skilled in the art that the control circuitry 180 of data storage devices of FIG. 3 and FIG. 4 can be easily derived from the control circuitry 180 shown in FIG. 6a by removing redundant control elements.

FIG. 6b shows an exemplary embodiment of the data path control part of control circuitry 180 for providing the appropriate data signals 124A-D to the first collection 122, the second collection 222, the third collection 322 and the fourth collection 422 of data storage elements 130. The data path control part of control circuitry 180 is implemented by multiplexers 690, 692, 694 and 696 under control of the selection signals S3-S6 from FIG. 6a. The data path control part of control circuitry 180 is arranged to select the number of appropriate number of inputs to the subdevices 122/222 and 322/422, i.e., a single input or two independent inputs. For instance, if subdevice 122/222 requires two different inputs, S3 and S5 will be set to the appropriate values to ensure that the first collection 122 of data storage elements 130 is coupled to either data input 124A or 124C, and the second collection 122 of data storage elements 130 is coupled to data input 124B. Again, it will be obvious to those skilled in the art that, dependent on the required flexibility in the electronic device 100, the data path control part of control circuitry 180 can be amended accordingly without departing from the scope of the present invention.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. An electronic device, comprising:
a data storage device for storing N data elements, N being an integer with a value of at least two, the data storage device comprising a first collection of data storage elements; and
an address decoder having an output coupled to the first collection of data storage elements for accessing a data storage element from the first collection of data storage elements on the basis of a bit pattern;
characterized by further comprising an address generator comprising a modulo-N counter for generating the bit pattern.

2. An electronic device, as claimed in claim 1, characterized by comprising a look-up table being operable as the first collection of data storage elements in a data storage configuration of the electronic device.

3. An electronic device as claimed in claim 1, characterized by being arranged to:
perform a read operation on the data storage element in a first phase of a control signal; and
perform a write operation on the data storage element in a second phase of the control signal.

4. An electronic device as claimed in claim 3, characterized in that a data storage element comprises a configurable switch coupled between a memory element and a data input of the data storage device; the configurable switch being conductive during at least a part of the second phase of the control signal.

5. An electronic device as claimed in claim 3, characterized by the data storage device further comprising a second collection of data storage elements in at least a data storage configuration of the electronic device; the electronic device further comprising control circuitry coupled between the control signal and the data storage device for selecting one of the first and second collection of data storage elements responsive to a selection signal.

6. An electronic device as claimed in claim 5, characterized by the second collection of data storage elements being responsive to the address decoder.

7. An electronic device as claimed in claim 5, characterized by the data storage device comprising a third collection of data storage elements and a fourth collection of data storage elements in at least the data storage configuration of the electronic device, the third collection and the fourth collection of data storage elements being responsive to a further address decoder;
the control circuitry further being arranged to select one of the first, second, third and fourth collection of data storage elements responsive to the selection signal and a further selection signal.

8. An electronic device as claimed in claim 7, characterized in that the selection signal and the further selection signal are derived from the most significant bits of the bit pattern.

9. An electronic device as claimed in claim 5, characterized in that the control circuitry further comprises a configuration network for configuring a size of the data storage device.
